(19) United States
(12) Patent Application Publication
(10) Pub. No.: US 2024/0322006 A1
(43) Pub. Date: Sep. 26, 2024

(54) HIGH BAND-GAP DEVICES WITH SELF-ALIGNED CONTACT

(71) Applicant: Texas Instruments Incorporated, Dallas, TX (US)

(72) Inventors: Dong Seup Lee, McKinney, TX (US); Jungwoo Joh, Allen, TX (US)

(21) Appl. No.: 18/189,870

(22) Filed: Mar. 24, 2023

(51) Int. Cl. H01L 29/66; H01L 29/20; H01L 29/40; H01L 29/778

(52) U.S. Cl. CPC H01L 29/66462; H01L 29/2003; H01L 29/404; H01L 29/7786

(57) ABSTRACT

A microelectronic device includes a GaN FET on a substrate such as silicon and a buffer layer of a GaN semiconductor material. The GaN FET includes a contact etch stop and a stretch contact electrically connecting a source region with the contact etch stop. The contact etch stop may stretch over a p-type GaN gate structure towards a drain region to form a field plate connected to the source region. The contact etch stop provides a method to connect the field plate to the source region which allows efficient area scaling of space between the source region and the p-GaN gate structure. Disclosed examples provide an associated process flow for forming such GaN FETs.

### TECHNICAL FIELD

This disclosure relates to the field of microelectronic devices. More particularly, but not exclusively, this disclosure relates to microelectronic devices including a field plate that provides a contact etch stop for forming a self-aligned contact connected to the field plate.

### BACKGROUND

Semiconductor components are being continually improved to operate with smaller feature sizes. Fabricating semiconductor components with field plates which meet area scaling requirements is challenging.

### SUMMARY

This summary is provided to introduce a brief selection of disclosed concepts in a simplified form that are further described below in the detailed description including the drawings provided. This summary is not intended to limit the claimed subject matter's scope.

Disclosed examples include microelectronic devices including a field effect transistor (FET). Examples in the disclosure disclose a gallium nitride field effect transistor (GaN FET) with a field plate over a gate of the GaN FET (e.g., p-type GaN gate). The field plate provides a contact etch stop while a contact of the GaN FET is formed. Subsequently, a metal layer provides electrical connection between the contact and the field plate. The field plate extended to and connected to the contact not only provides a method to connect the field plate to the contact but also facilitates efficient area scaling of the space between the contact and the gate of the GaN FET. The method may be applied to other microelectronic devices with a field plate. Disclosed examples provide an example process flow and associated options for forming such GaN FETs for microelectronic devices.

### BRIEF DESCRIPTION OF THE VIEWS OF THE DRAWINGS

FIG. 1A through FIG. 1G are cross sections of an example microelectronic device with a GaN FET containing a contact etch stop depicted in successive stages of an example method of formation.

FIG. 2 is a cross section of an example microelectronic device with a GaN FET containing contact etch stops.

FIG. 3A through FIG. 3E are cross sections of an example microelectronic device with a GaN FET containing a contact etch stop depicted in successive stages of an example method of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure is illustrated by embodiments directed to active devices, it is not intended that these illustrations be a limitation on the scope or applicability of the present disclosure. It is not intended that the active devices of the present disclosure be limited to the physical structures illustrated. These structures are included to demonstrate the utility and application of the present disclosure to presently preferred embodiments.

For the purposes of this description, the term “III-N” is understood to refer to semiconductor materials in which group III elements, such as aluminum, gallium, and indium, and possibly boron, provide a portion of the atoms in the semiconductor material and nitrogen atoms provide another portion of the atoms in the semiconductor material. Examples of III-N semiconductor materials include gallium nitride, boron gallium nitride, aluminum gallium nitride, indium nitride, and indium aluminum gallium nitride. Terms describing elemental formulas of materials do not imply a particular stoichiometry of the elements. For example, aluminum gallium nitride may be written as AlGaN, which covers a range of relative proportions of aluminum and gallium.

It is noted that terms such as top, bottom, over, above, and under may be used in this disclosure. These terms should not be construed as limiting the position or orientation of a structure or element, but should be used to provide spatial relationship between structures or elements. The terms “lateral” and “laterally” refer to directions parallel to a plane corresponding to a surface of a layer, for example a top surface of a channel layer.

Semiconductor components are being continually improved to operate with smaller feature sizes. Fabricating semiconductor components with field plates which meet area scaling requirements is challenging. For field plates in microelectronic devices, it may be advantageous to use a stretch contact and a contact etch stop to directly connect a field plate to a contact region. This advantage can be used with any FET which contains a field plate. The example device in the disclosure is a gallium nitride field effect transistor (GaN FET), which is a high band-gap (e.g., a band-gap greater than that of silicon, in some cases, high band-gap being more than 2 eV) transistor with a heterojunction structure. In some examples, the heterojunction structure includes a channel layer of a first III-N material over a substrate (e.g., a semiconductor substrate) and a barrier layer of a second III-N material on the channel layer. Such a GaN FET may have a p-type doped III-N layer (which may also be referred to as a p-type GaN layer) between a gate metal layer and the channel layer. A gate for the GaN FET may include at least a portion of the p-type GaN layer and at least a portion of the gate metal layer, which may be referred to as a gate electrode p-type GaN stack. The p-type GaN layer may be regarded as floating due to the Schottky diode nature between the p-type GaN layer and the gate metal layer of the gate electrode p-type GaN stack.

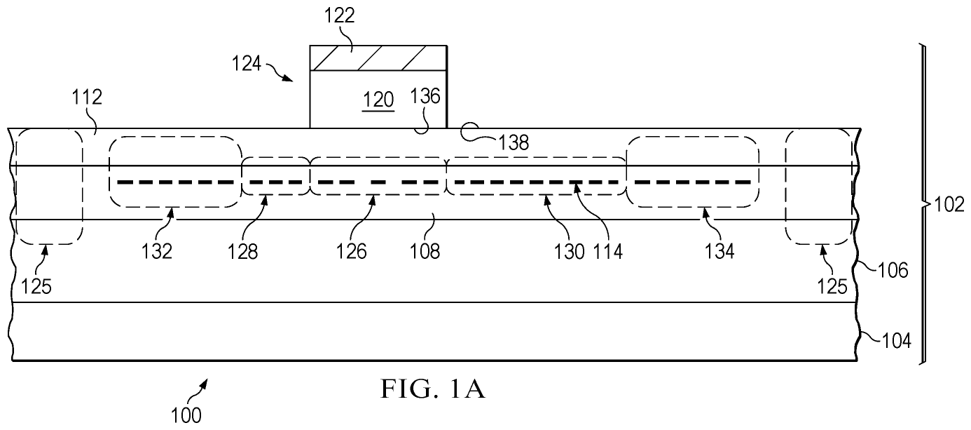

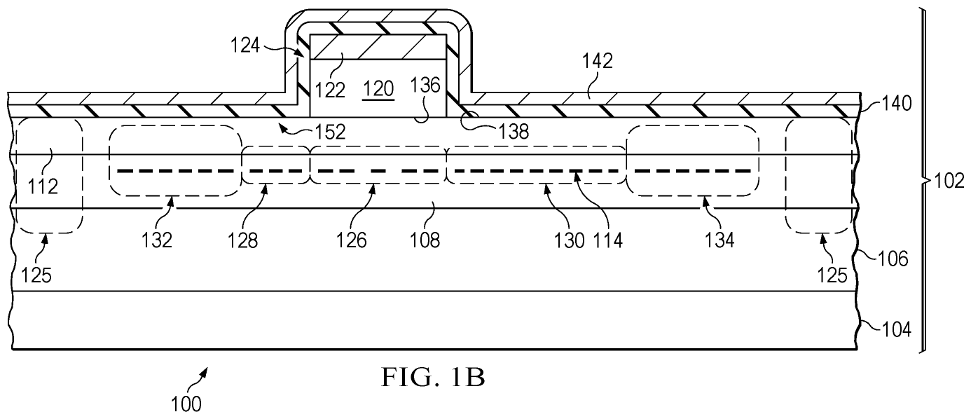

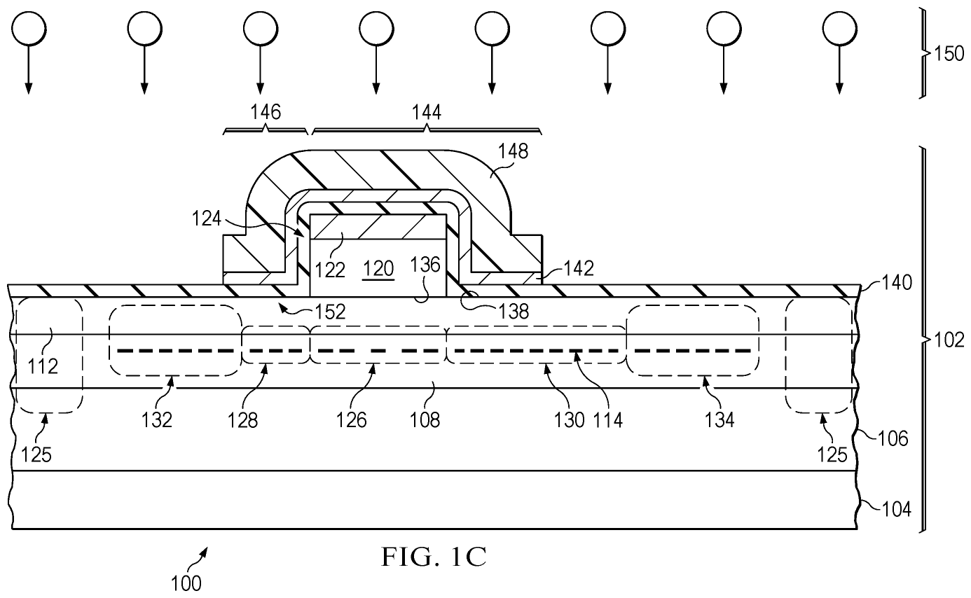

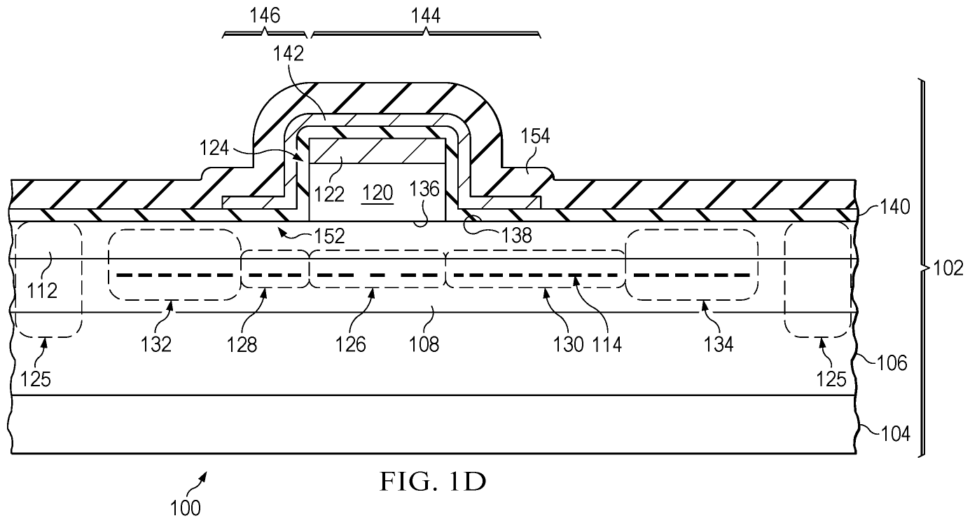

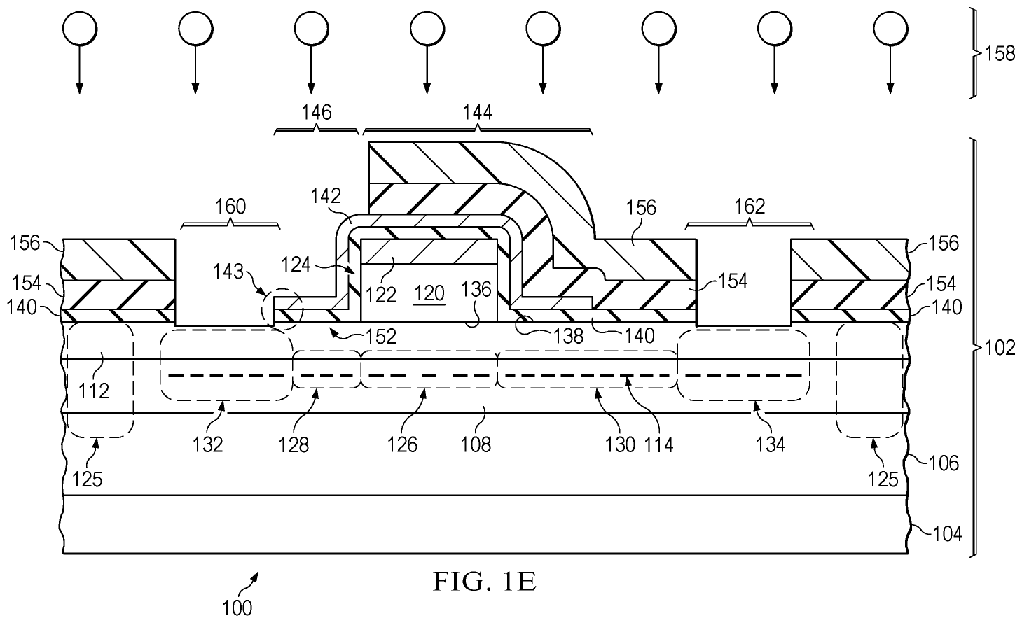

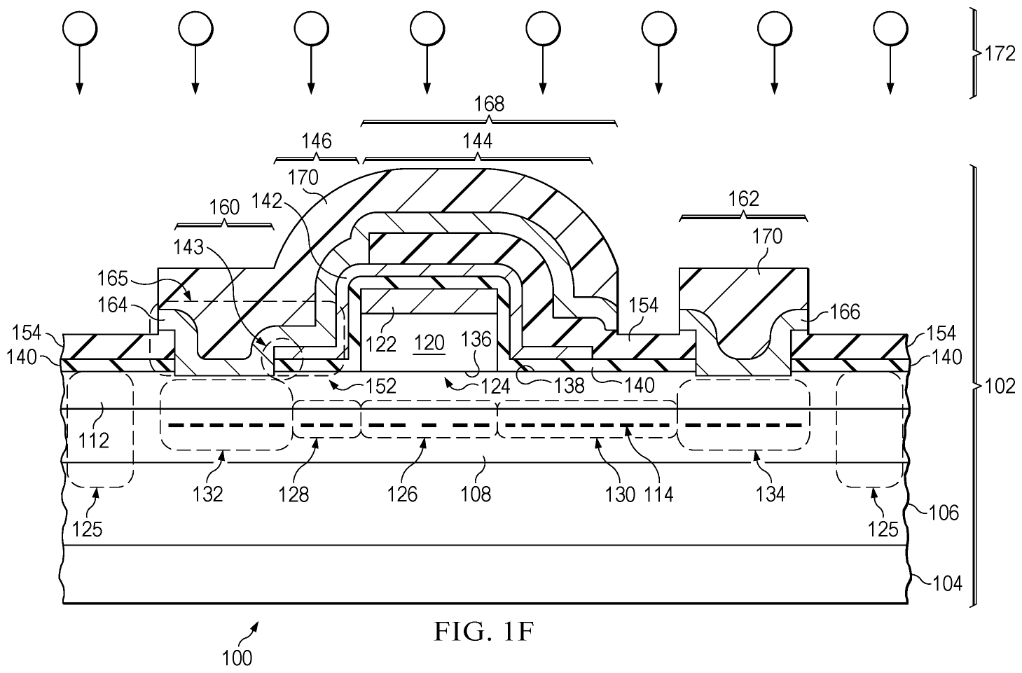

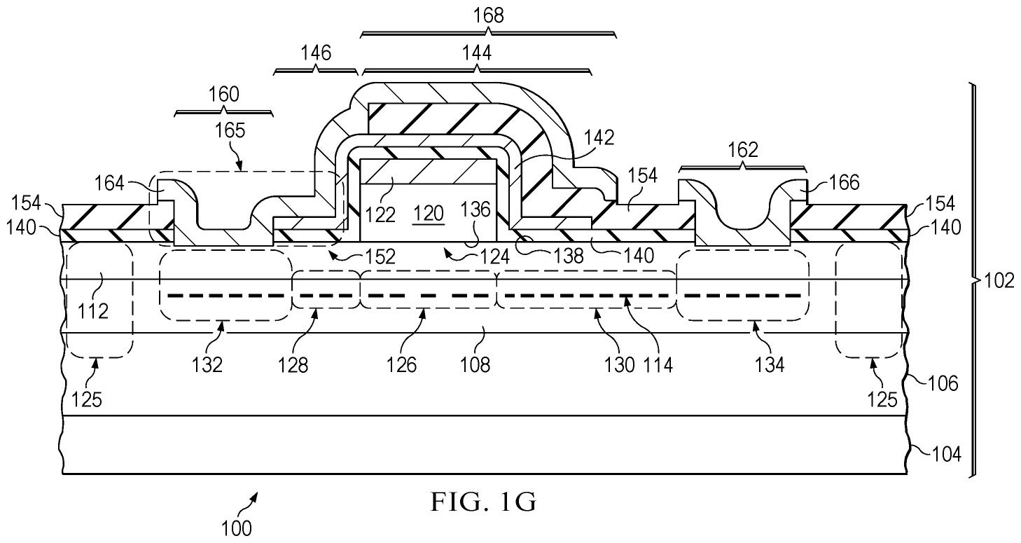

FIG. 1A through FIG. 1G are cross sections of an example microelectronic device 100 with a GaN FET 102 containing a contact etch stop depicted in successive stages of an example method of formation. FIG. 1A shows a cross section of the microelectronic device 100 including the GaN FET 102 at a point in an example method of forming the GaN FET 102 after a gate structure (herein referred to as a gate electrode p-type GaN stack or a gate electrode GaN stack 124) has been defined.

Prior to forming the gate electrode p-type GaN stack 124 shown in FIG. 1A, the method may include forming a buffer layer 106 on a substrate 104. In versions of this example in which the substrate 104 is implemented as a silicon wafer or a sapphire wafer, the buffer layer 106 may include a nucleation layer having a stoichiometry that includes aluminum, to match a lattice constant of the substrate 104. The buffer layer 106 may further include sublayers of gallium aluminum nitride with decreasing aluminum content, culminating in an unintentionally doped gallium nitride layer. The buffer layer 106 on silicon or sapphire may be 1 micron (μm) to several microns thick. In versions of this example in which the substrate 104 is implemented as a silicon carbide wafer, the buffer layer 106 may be thinner, due to a closer match in lattice constant between gallium nitride and silicon carbide. The buffer layer 106 may be formed by a buffer metal organic vapor phase epitaxy (MOVPE) process with several operations to form the nucleation layer and sublayers. The buffer layer 106 overlaps an area for the GaN FET 102.

After the formation of the buffer layer 106, a channel layer 108 of III-N semiconductor material is formed on the buffer layer 106. The channel layer 108 includes gallium and nitrogen, and may include primarily gallium nitride, with optional trace amounts of other group III elements, such as aluminum or indium. The channel layer 108 may be formed by a channel MOVPE process using a gallium containing gas reagent and a nitrogen containing gas reagent. The substrate 104 may be heated to 900° C. to 1100° C. during the channel MOVPE process. The gallium containing gas reagent may be implemented as trimethylgallium or triethylgallium, for example. The nitrogen containing gas reagent may be implemented as ammonia, hydrazine, or 1,1 dimethylhydrazine, for example. The channel MOVPE process uses a carrier gas. The carrier gas may include primarily hydrogen gas, or may include hydrogen with another gas such as nitrogen. The channel layer 108 may be 1 nanometer (nm) to 10 nanometers thick, by way of example. In an alternate version of this example, the channel layer 108 may be formed as a last portion of the buffer layer 106. During operation of the GaN FET 102, the channel layer 108 supports a 2-dimensional electron gas (2DEG) 114.

After the formation of the channel layer 108, a barrier layer 112 of III-N semiconductor material is formed over the channel layer 108. The barrier layer 112 may include aluminum and nitrogen. In one version of this example, the barrier layer 112 may also include gallium (AlₓGa_{y}N) where the sum of x and y equals one, and x and y can range between 0.01 and 0.99. In another version of this example, the barrier layer 112 may have a stoichiometry of Al_{.83}In_{.17}N, within a few atomic percent, which provides a close lattice match to gallium nitride. In a further version, the barrier layer 112 may include gallium and indium; the gallium may improve uniformity of the indium in the barrier layer 112. The barrier layer 112 may have a thickness of 1 nanometer to 600 nanometers, by way of example. The barrier layer 112 induces the 2DEG 114 in the channel layer 108 adjacent to the barrier layer 112. The stoichiometry and thickness of the barrier layer 112 may provide a free charge carrier density of 3×10¹² cm⁻² to 2×10¹³ cm⁻² to provide a desired on-state resistance for the GaN FET 102. The channel layer 108 and the barrier 112 may be collectively referred to as a heterojunction layer (or a heterojunction structure).

The barrier layer 112 may be formed by a barrier MOVPE process using an aluminum containing gas reagent and a nitrogen containing gas reagent. The aluminum containing gas reagent may be implemented as trimethylaluminum or triethylaluminum, for example. The nitrogen containing gas reagent may be implemented as ammonia, hydrazine, or 1,1 dimethylhydrazine, as disclosed in reference to forming the channel layer 108. In versions of this example in which the barrier layer 112 includes gallium, the barrier MOVPE process uses a gallium containing gas reagent in addition to the aluminum containing gas reagent and the nitrogen containing gas reagent. The gallium containing gas reagent may be implemented as trimethylgallium or triethylgallium, as disclosed in reference to forming the channel layer 108. In versions of this example in which the barrier layer 112 includes indium, the barrier MOVPE process uses an indium containing gas reagent. The indium containing gas reagent may be implemented as trimethylindium or tricthylindium, for example. The barrier MOVPE process uses a carrier gas. The carrier gas may include primarily hydrogen gas, or may include hydrogen with another gas such as nitrogen. The substrate 104 may be heated to 900° C. to 1100° C. during the barrier MOVPE process.

After the formation of the barrier layer 112, an optional etch stop layer (not specifically shown) may be formed on the barrier layer 112. The optional etch stop layer may have a higher aluminum content than the barrier layer 112. The optional etch stop layer may include a primarily aluminum nitride semiconductor material. The optional etch stop layer may be 0.5 nanometers to 3 nanometers thick. The optional etch stop layer may advantageously reduce or eliminate etching of the barrier layer 112 during a subsequent gate etch process.

A p-type III-N semiconductor material referred to herein as a p-type GaN layer 120 (or a p-type GaN gate layer 120) may be formed as a layer over the barrier layer 112. The p-type GaN layer 120 may include primarily gallium nitride, with magnesium dopant to provide p-type conductivity. In some versions of this example, the p-type GaN layer 120 may include other group III elements, such as aluminum or indium, at less than 10 atomic percent. The p-type GaN layer 120 may be 5 nanometers to 500 nanometers thick, to provide a desired threshold potential for the GaN FET 102. The p-type GaN layer 120 reduces the free charge carrier density (e.g., electron density) in the 2DEG 114, for example by 25 percent to 99 percent, as a result of the work function of the p-type GaN layer reducing the quantum well in the channel layer 108. The 2DEG 114 may retain a finite free charge carrier density of electrons after the p-type GaN layer 120 is formed.

The p-type GaN layer 120 may be formed by a MOVPE process using a gallium containing gas reagent, a nitrogen containing gas reagent, and a p-type dopant gas. The gallium containing gas reagent may be implemented as trimethylgallium or triethylgallium, for example. The nitrogen containing gas reagent may be implemented as ammonia, hydrazine, or 1,1 dimethylhydrazine, as disclosed in reference to forming the channel layer 108. The p-type dopant gas reagent may be implemented as bis(cyclopentadienyl)magnesium, by way of example. Other sources of magnesium containing gas reagents are within the scope of this example. Further, other implementations of the p-type dopant gas to provide p-type dopants other than magnesium are also within the scope of this example. In versions of this example in which the p-type dopant is implemented as magnesium, the magnesium concentration in the p-type GaN layer 120 may be 1×10¹⁷ cm⁻³ to 1×10²⁰ cm⁻³ to provide a desired threshold potential for the GaN FET 102.

In versions of this example in which the p-type GaN layer 120 includes aluminum, the MOVPE process uses an aluminum containing gas reagent. The aluminum containing gas reagent may be implemented as trimethylaluminum or tricthylaluminum, as disclosed in reference to forming the barrier layer 112. In versions of this example in which the p-type GaN layer 120 includes indium, the MOVPE process uses an indium-containing gas reagent. The indium containing gas reagent may be implemented as trimethylindium or triethylindium, as disclosed in reference to forming the barrier layer 112. The MOVPE process forming the p-type GaN layer 120 uses a carrier gas. The carrier gas may include primarily hydrogen gas, or may include hydrogen with another gas such as nitrogen. The substrate 104 may be heated to 900° C. to 1100° C. during the MOVPE process.

A gate metal layer 122 may then be formed on the p-type GaN layer 120. The gate metal layer 122 may include titanium, nickel, titanium nitride, titanium tungsten, tungsten, or a combination thereof. Other metals for the gate metal layer 122 are within the scope of the disclosure. The gate metal layer 122 may be deposited by a sputtering process, a plasma deposition process, or a chemical vapor deposition (CVD) process. The gate metal layer 122 is between 50 nanometers to 3 microns thick by way of example.

Still referring to FIG. 1A, the method may include forming an isolation region 125 surrounding the GaN FET 102. To form the isolation region 125, a photolithography step may be used to cover an area of the GaN FET 102 with photoresist, leaving the isolation region 125 exposed to an isolation region implant (not specifically shown). The isolation region implant may include an implant of argon, fluorine, or nitrogen ions implanted with an energy and an implant dose sufficient to create an amorphous region of damage during the formation of the isolation region 125 which results in increased resistance of the exposed layers such that acceptable isolation characteristics are achieved for the functionality of the GaN FET 102. The isolation region 125 may also be formed using a photolithography step to cover the area of the GaN FET 102 leaving the isolation region 125 exposed, followed by an etch process which removes the barrier layer 112, the channel layer 108, and a portion of the buffer layer 106.

The method may include a photolithographic pattern and plasma etch process used to define and etch the gate metal layer 122 and the p-type GaN layer 120 to form the gate electrode p-type GaN stack 124 as shown in FIG. 1A. In the gate electrode p-type GaN stack 124 formation process, a gate mask (not specifically shown) is formed on the gate metal layer 122, the gate mask covering an area of the gate metal layer 122 and underlying p-type GaN layer 120. In one version of this example, the gate mask may include photoresist, formed directly by a photolithographic process. The gate mask may include organic anti-reflection material such as a bottom anti-reflection coat (BARC) layer under the photoresist. The BARC layer may be patterned after the photolithographic process is completed. In another version of this example, the gate mask may include various hard mask materials, such as silicon dioxide or silicon nitride. The hard mask material may be patterned by forming a photoresist pattern over the hard mask material, followed by etching the hard mask material using a reactive ion etch (RIE) process or an ion milling process. A hard mask material in the gate mask may provide improved control of the lateral dimension of the gate electrode p-type GaN stack 124. The gate electrode p-type GaN stack 124 formation process continues with a gate etch process (not specifically shown) which removes the gate metal layer 122 and p-type GaN layer 120 where exposed by the gate mask, leaving the gate metal layer 122 and p-type GaN layer 120 under the gate mask to form the gate electrode p-type GaN stack 124.

Still referring to FIG. 1A, the 2DEG 114 includes a channel region 126 under the gate electrode p-type GaN stack 124. Also, the 2DEG 114 includes a source access region 128 and a drain access region 130, both adjacent to the channel region 126. The free charge carrier density in the channel region 126 may be less than that in a source access region 128 and a drain access region 130 of the 2DEG 114 because the thickness of the p-type GaN layer 120 remains the same as formed in the gate electrode p-type GaN stack 124. In other words, the free charge carrier density in the source access region 128 and the drain access region 130 may be greater than that in the channel region 126 because the gate metal layer 122 and p-type GaN layer 120 are removed in the source access region 128 and the drain access region 130.

The 2DEG 114 includes a source region 132 in an area for a source of the GaN FET 102. The source region 132 is laterally separated from the channel region 126 by the source access region 128. Similarly, the 2DEG 114 includes a drain region 134 in an area for a drain of the GaN FET 102. The drain region 134 is laterally separated from the channel region 126 by the drain access region 130, and is located opposite from the source region 132.

The free charge carrier density of the 2DEG 114 in the source access region 128 and the drain access region 130 after the gate electrode p-type GaN stack 124 formation may increase to a value comparable to the free charge carrier density before the p-type GaN layer 120 (and the gate metal layer 122) was formed. The free charge carrier density of the 2DEG 114 in the source access region 128 and drain access region 130 may be 3×10¹² cm⁻² to 2×10¹³ cm⁻² to provide the desired on-state resistance for the GaN FET 102. The channel region 126 of the 2DEG 114 may retain a non-zero density of electrons, for example, 1 percent to 75 percent of the free charge carrier density of the 2DEG 114 in the source access region 128 and the drain access region 130.

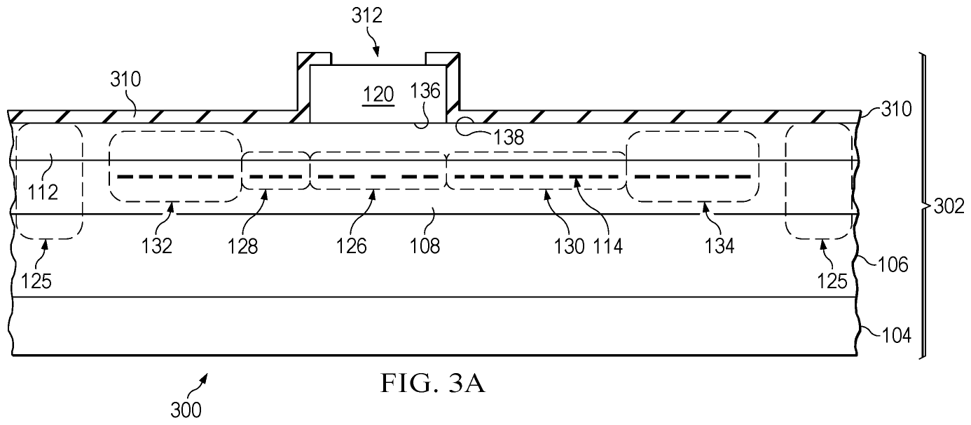

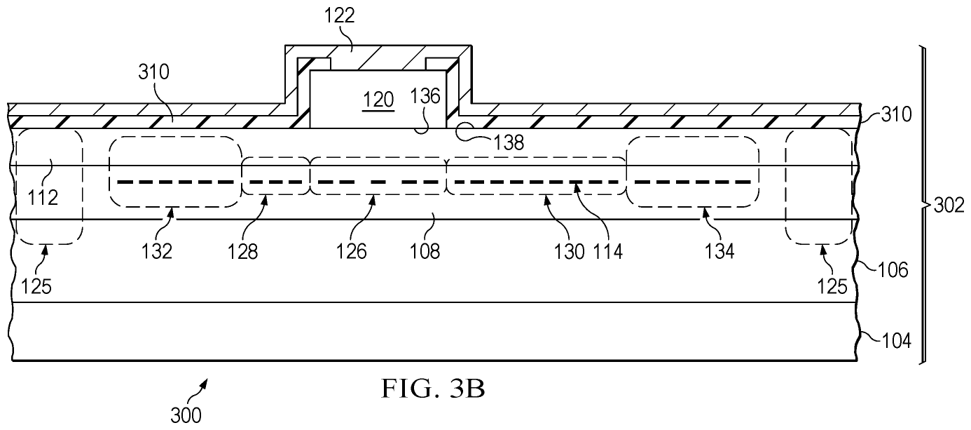

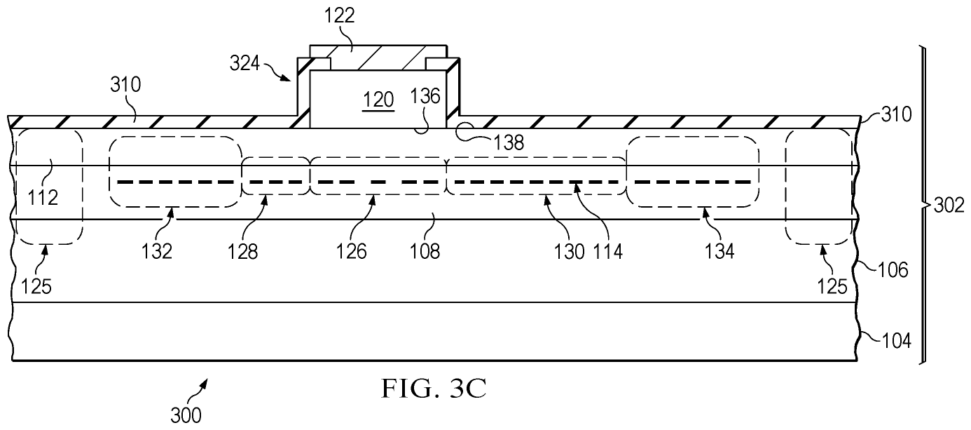

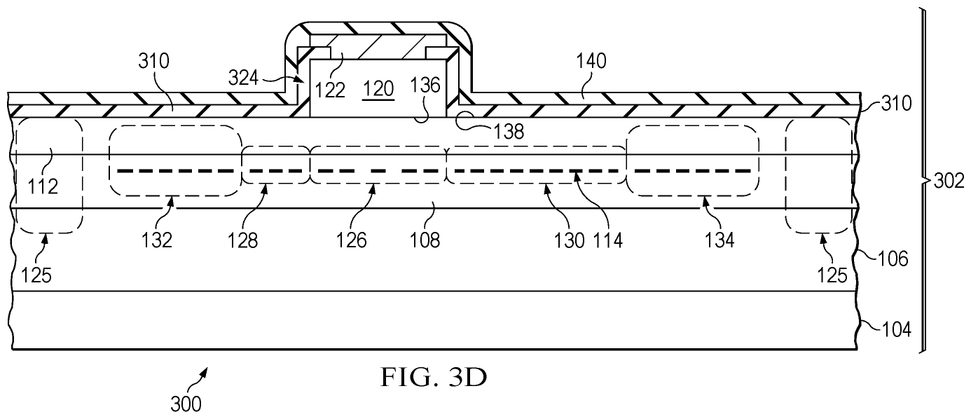

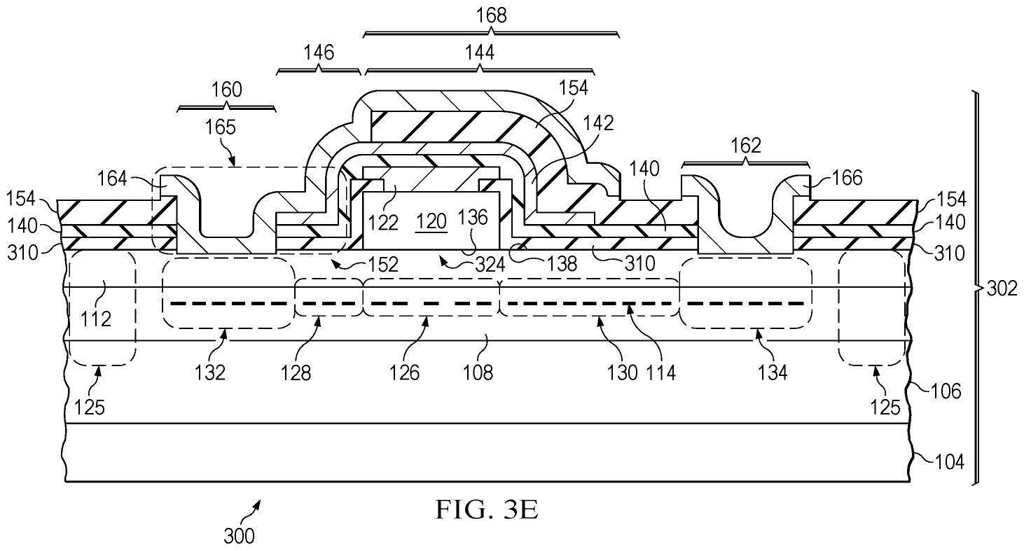

The bottom surface 136 of the gate electrode p-type GaN stack 124, adjacent to the barrier layer 112, may not extend past the top surface 138 of the barrier layer 112 located opposite from the channel layer 108 such that the GaN FET 102 can be formed without a gate recess etch. Moreover, the GaN FET 102 may be free of any dielectric material between the gate electrode p-type GaN stack 124 and the barrier layer 112 such that the GaN FET 102 can be formed without including a gate dielectric layer. The gate recess etch or the gate dielectric layer tend to increase fabrication cost and complexity. The GaN FET 102 may be free of III-N semiconductor material adjacent to the gate electrode p-type GaN stack 124, which may extend above the bottom surface 136 of the gate electrode p-type GaN stack 124, advantageously enabling the GaN FET 102 to be formed without forming a barrier regrowth layer, which also tends to increase fabrication cost and complexity. Other methods of forming the gate electrode p-type GaN stack 124 are within the scope of this disclosure. For example, as described with reference to FIGS. 3A through 3E, the p-type GaN layer 120 and the gate metal layer 122 may be separately patterned to form a gate electrode GaN stack.

FIG. 1B through FIG. 1G are cross sections of the remaining steps to form the GaN FET 102. Referring to FIG. 1B, a first dielectric layer 140 is formed over the gate electrode p-type GaN stack 124 and over the barrier layer 112 adjacent to the gate electrode p-type GaN stack 124. The first dielectric layer 140 may include one or more sublayers of silicon dioxide, silicon nitride, aluminum oxide, or any combination thereof. The first dielectric layer 140 may be formed by one or more low pressure chemical vapor deposition (LPCVD) processes, plasma enhanced chemical vapor deposition (PECVD) processes, high density plasma (HDP) processes, or atomic layer deposition (ALD) processes, by way of example. The first dielectric may range in thickness from 1 nanometer to 200 nanometers by way of example.

After the first dielectric layer 140 is formed, a first field plate metal layer 142 is formed over the first dielectric layer 140. The first field plate metal layer 142 forms a first field plate 144 and a contact etch stop 146 as described with reference to FIG. 1C. The first field plate metal layer 142 may be a metal, such as TiW. W. TiN, a bilayer of aluminum and titanium, or a metal sandwich of TiN/Al/Ti by way of example. In some examples, the first field plate metal layer 142 may be based on an aluminum-based metallization system. For example, the first field plate metal layer 142 may include an adhesion layer, not explicitly shown, of titanium nitride or titanium tungsten, on the first dielectric layer 140, an aluminum layer with a few atomic percent of silicon, titanium, or copper, on the adhesion layer, and an anti-reflection layer, not explicitly shown, of titanium nitride on the aluminum layer. The first field plate metal layer 142 may be deposited using a physical vapor deposition (PVD) deposition method or other suitable process techniques. The thickness of the first field plate metal layer 142 may be between 30 nanometers and 500 nanometers.

Referring to FIG. 1C, the formation of the first field plate 144 and the contact etch stop 146 from the first field plate metal layer 142 is shown. After the formation of the first field plate metal layer 142, a photoresist layer 148 is patterned to define the area of the first field plate 144 and contact etch stop 146 followed by a first field plate etch 150 which removes the first field plate metal layer outside of the region of the first field plate 144 and contact etch stop 146. The example shown for the GaN FET 102 is for a source side field plate. While the first field plate 144 is a source side field plate, it may also be placed on the drain side where it may be advantageous.

The first field plate metal layer 142 that remains after the first field plate etch 150 functions as a first field plate 144 and a contact etch stop 146. The contact etch stop 146 corresponds to the portion of the first field plate metal layer 142 that stretches from the top source side corner of the gate electrode p-type GaN stack 124 and extends to the edge (e.g., border or boundary) of the source region 132 facing the gate electrode p-type GaN stack 124. The contact etch stop 146 forms a border of the source contact opening 160 (described with reference to FIG. 1E) facing toward the gate electrode p-type GaN stack 124. It is advantageous for the first field plate 144 to overlap the vertical edges (or sidewalls) of the gate electrode p-type GaN stack 124 to prevent a shorting mechanism and/or a reliability failure mechanism that could be caused by unintended metal residues that may remain on the sidewalls of the first dielectric layer 140 if the photoresist layer 148 is designed to expose the first field plate metal layer 142 over the sidewalls of the gate electrode p-type GaN stack 124.

A portion of the contact etch stop 146 extending past the vertical edge of the gate electrode p-type GaN stack 124, denoted as a contact etch stop extension 152 in FIG. 1C, will be connected to a subsequently formed metal layer 164 that forms a stretch contact 165 (shown in FIG. 1F). In this manner, an electrical connection between the source region 132 and the contact etch stop extension 152 (which is part of the contact etch stop 146) is established as described with reference to FIG. 1F. As such, the source region 132 (connected to the contact etch stop extension 152 through the metal layer 164) is electrically connected to the first field plate 144 (which is a portion of the contiguous first field plate metal layer 142 remaining after the first field plate etch 150).

As described above, the first field plate 144 and contact etch stop 146 are continuous and are formed from the first field plate metal layer 142, but have different functions. The first field plate 144 functions as a field plate (e.g., mitigating a peak electric field so as to increase breakdown voltages of semiconductor devices) for the GaN FET 102 while the contact etch stop 146 facilitates forming a self-aligned contact opening—e.g., the source contact opening 160 described with reference to FIG. 1E. Moreover, the contact etch stop 146 functions both as a means to connect the first field plate 144 to a contact metal layer 164 (described with reference to FIGS. 1F and 1G), and by covering the vertical edge of the gate electrode p-type GaN stack 124 on the source side of the gate electrode p-type GaN stack 124, as a means to prevent any remaining metal residue formation over the sidewall of the gate electrode p-type GaN stack 124 during the first field plate etch 150.

Referring to FIG. 1D, a second dielectric layer 154 is formed over the first field plate 144, contact etch stop 146, and exposed first dielectric layer 140. The second dielectric layer 154 may include one or more sublayers of silicon dioxide, silicon nitride, aluminum oxide, or any combination thereof. The second dielectric layer 154 may be formed by one or more low pressure chemical vapor deposition (LPCVD) processes, plasma enhanced chemical vapor deposition (PECVD) processes, high density plasma (HDP) processes, or atomic layer deposition (ALD) processes, by way of example. The second dielectric may range in thickness from 10 nanometers to 500 nanometers.

Referring to FIG. 1E, a patterned photoresist layer 156 and a plasma etch process 158 are used to remove the first dielectric layer 140 and second dielectric layer 154 in the region over the source region 132 and the drain region 134. The plasma etch process 158 also removes the second dielectric layer 154 over the contact etch stop 146. The plasma etch process 158 is configured to preserve the contact etch stop 146 while removing the first and second dielectric layers 140 and 154. In this regard, the contact etch stop 146 may function as a hard mask layer against the plasma etch process 158. Accordingly, the patterned photoresist layer 156 provides a self-aligned edge (border or boundary) of the source contact opening 160. In other words, a portion of the source contact opening 160 (e.g., a portion facing opposite the gate electrode p-type GaN stack 124) is defined by the edge of the patterned photoresist layer 156, and a portion of the source contact opening 160 (e.g., a portion facing the gate electrode p-type GaN stack 124) is defined by the edge (or end) of the contact etch stop 146, not by the patterned photoresist layer 156. As such, at the source contact opening 160 facing the gate electrode p-GaN stack 124 (as indicated by the circle 143), an end of the contact etch stop extension 152 may be aligned with an end of the first dielectric layer 140 underneath it, at least partially due to anisotropic etch characteristics of the plasma etch process 158. FIG. 1E also shows a drain contact opening 162 formed as a result of the plasma etch process 158.

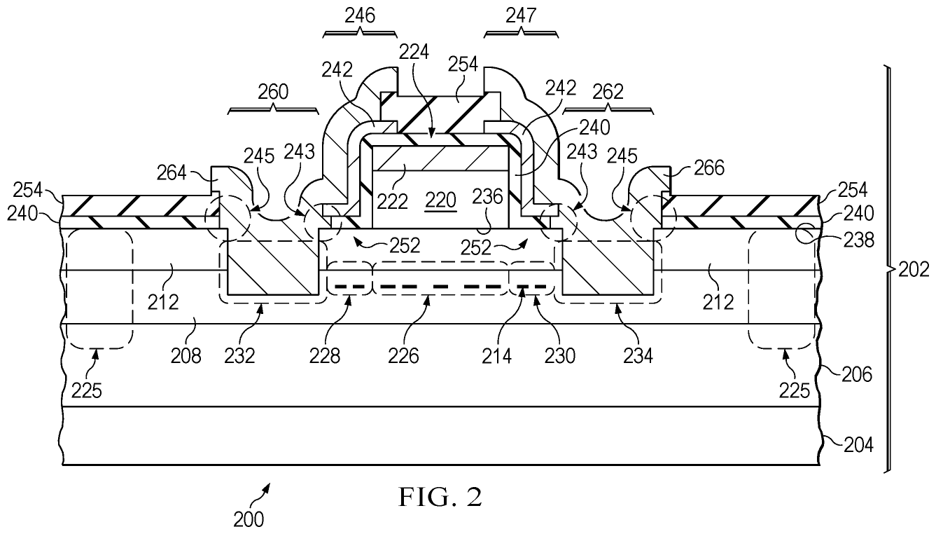

Subsequently, an etch clean process (e.g., a wet clean process having isotropic etch characteristics) may be optionally carried out. The etch clean process may remove by-products (e.g., polymers) produced and formed at sidewalls of etched surfaces. In some examples, the etch clean process may remove portions of the first and/or second dielectric layers (e.g., to ensure thorough removal of the by-products) while preserving the first field plate metal layer 142. The etch clean process may be carried out after removing the patterned photoresist layer 156 or with the patterned photoresist layer 156 in place. Accordingly, if the etch clean process (not specifically shown) etches the first dielectric layer 140 underneath the patterned first field plate metal layer 142, the first dielectric layer 140 may be recessed with respect to the contact etch stop 146 at the source side. Moreover, a step (or a ledge) may form at the border of the source contact opening 160 (e.g., the border of the source contact opening 160 facing opposite the gate electrode p-GaN stack 124) as well as at the borders of the drain contact opening 162 as a result of the etch clean process removing the first and second dielectric layers 140 and 154. Such features are described in more detail with reference to FIG. 2.

Referring to FIG. IF, after removing the patterned photoresist layer 156 (and after an optional etch clean process in some cases), a metal layer 164 may be formed over the second dielectric layer 154, the drain contact opening 162, the source contact opening 160, and the contact etch stop 146. The second dielectric layer 154 is disposed between the first field plate 144 and the metal layer 164. By way of example, the metal layer 164 may be aluminum, tungsten, titanium, titanium nitride, or other conducting material. A patterned photoresist layer 170 is formed on the metal layer 164 and a plasma etch process 172 removes the metal layer 164 in the exposed areas of the patterned photoresist layer 170. After the plasma etch process 172, the remaining portion of the metal layer 164 forms a stretch contact 165 which at least partially extends over the contact etch stop 146 and provides an electrical contact between the source region 132 and the contact etch stop 146. The metal layer 164 may optionally extend over a portion of the second dielectric layer 154 over the gate electrode p-type GaN stack 124 towards the drain region 134 to form an optional second field plate 168. In this manner, the first and second field plates 144 and 168 are connected to the source of the GaN FET 102 at the self-aligned source contact opening 160 filled with the metal layer 164.

Referring to FIG. 1G, the microelectronic device 100 including the GaN FET 102 is shown after the removal of the patterned photoresist layer 170. In the microelectronic device 100, the drain contact metal 166 is isolated from the portion of the metal layer 164 in the source contact opening 160. The metal layer 164 makes an electrical contact to the source region 132, and couples the source region 132 to the contact etch stop 146 at the self-aligned border of the source contact opening 160 (e.g., the border of the source contact opening 160 facing the gate electrode p-type GaN stack 124). Moreover, the metal layer 164 forms the stretch contact 165 in contact with the contact etch stop extension 152. The metal layer 164 may be continuous (e.g., extends from the source contact opening 160) over the gate electrode p-type GaN stack 124 to form the optional second field plate 168.

FIG. 2 is a cross section of an example microelectronic device 200 with a GaN FET 202 containing contact etch stops. The GaN FET 202 may include aspects of the GaN FET 102. The GaN FET 202 include a substrate 204 (e.g., the substrate 104) and a buffer layer 206 (e.g., the buffer layer 106) on the substrate 204. A channel layer 208 (e.g., the channel layer 108) of III-N semiconductor material is formed on the buffer layer 206. During operation of the GaN FET 202, the channel layer 208 supports a 2DEG 214 (e.g., the 2DEG 114). Moreover, a barrier layer 212 (e.g., the barrier layer 112) of III-N semiconductor material is formed over the channel layer 208.

The barrier layer 212 induces the 2DEG 214 in the channel layer 208 adjacent to the barrier layer 212. The stoichiometry and thickness of the barrier layer 212 may provide a free charge carrier density of 3×10¹² cm⁻² to 2×10¹³ cm⁻² to provide a desired on-state resistance for the GaN FET 202.

In some examples, a p-type GaN layer 220 (e.g., the p-type GaN layer 120) and a gate metal layer 222 (e.g., the gate metal layer 122) are deposited. Subsequently, a photolithographic patterning and etching of the p-type GaN layer 220 and the gate metal layer 222 are carried out to form a gate electrode p-type GaN gate stack 224. In other examples, the p-type GaN layer 220 and the gate metal layer 222 may be separately patterned to form a gate electrode p-type GaN gate stack as described with reference to FIGS. 3A through 3E. An isolation region 225 (e.g., the isolation region 125) may be formed surrounding the GaN FET 202.

The 2DEG 214 includes a channel region 226 under the gate electrode p-type GaN stack 224. As described above with reference to FIG. 1A, the free charge carrier density in the channel region 226 may be lower than in the source access region 228 and the drain access region 230. In other words, the free charge carrier density in the 2DEG 214 may be greater in the source access region 228 and the drain access region 230 than in the channel region 226.

The 2DEG 214 contacts a source region 232 in an area for a source of the GaN FET 202. The source region 232 is laterally separated from the channel region 226 by the source access regions 228. Similarly, the 2DEG 214 contacts a drain region 234 in an area for a drain of the GaN FET 202. The drain region 234 is laterally separated from the channel region 226 by the drain access region 230, and is located opposite from the source region 232. As with the GaN FET 102, the bottom surface 236 of the gate electrode p-type GaN stack 224, adjacent to the barrier layer 212, may not extend past the top surface 238 of the barrier layer 212 located opposite from the channel layer 208.

In a similar fashion to the process steps described with reference to FIG. 1A through FIG. 1G, a first dielectric layer 240 (e.g., the first dielectric layer 140) is formed over the barrier layer 212 and gate electrode p-type GaN stack 224. The first dielectric layer 240 may include one or more sublayers of silicon dioxide, silicon nitride, aluminum oxide, or any combination thereof. Moreover, a first metal layer 242 (e.g., the first field plate metal layer 142) is formed on the first dielectric layer 240, which forms a source side contact etch stop 246 and a drain side contact etch stop 247 at subsequent process steps.

As shown in FIG. 2, the source side contact etch stop 246 extends from the top source side corner of the gate electrode p-type GaN stack 224, over the source side edge of the gate electrode p-type GaN stack 224, towards the source region 232. Similarly, the drain side contact etch stop 247 extends from the top drain side corner of the gate electrode p-type GaN stack 224, over the drain side edge of the gate electrode p-type GaN stack 224, towards the drain region 234. As with the contact etch stop 146, the source side contact etch stop 246 and the drain side contact etch stop 247 may include a metal, such as TiW, W. TiN, a bilayer of aluminum and titanium, or a metal sandwich of TiN/Al/Ti. In some cases, the source side contact etch stop 246 and the drain side contact etch stop 247 may be based on an aluminum-based metallization system. Contact etch stop extensions 252 past the vertical edges of the gate electrode p-type GaN stack 224 (e.g., portions of the source side contact etch stop 246 and the drain side contact etch stop 247, respectively) determine the space between the gate electrode p-type GaN stack 224 and the edge (boundary or border) of the source region 232 facing the gate electrode p-type GaN stack 224 and the space between the gate electrode p-type GaN stack 224 and the edge (boundary or border) of the drain region 234 facing the gate electrode p-type GaN stack 224.

A second dielectric layer 254 (e.g., the second dielectric layer 154) is formed over the source side contact etch stop 246 and the drain side contact etch stop 247 as well as over the exposed first dielectric layer 240. The second dielectric layer 254 may include one or more sublayers of silicon dioxide, silicon nitride, aluminum oxide, or any combination thereof. A subsequent pattern and etch step (e.g., the plasma etch process 158) removes the first and second dielectric layers 240 and 254 in the source region 232. the drain region 234. Moreover, the etch step removes the second dielectric layer 254 over the source side etch stop 246 and the drain side etch stop 247. As described with reference to FIG. 1E, the source side etch stop 246 and the drain side etch stop 247 provides portions of the source side opening 260 and the drain side opening 262 to be self-aligned—e.g., respective edges (or borders) of the source side opening 260 and the drain side opening 262 facing the gate electrode p-type GaN stack 224 that are defined by the source side etch stop 246 and the drain side etch stop 247. In this regard, the source side etch stop 246 and the drain side etch stop 247 may function as a hard mask layer against the plasma etch process (e.g., the plasma etch process 158).

An optional etch clean step (e.g., a wet clean process having isotropic etch characteristics) may be carried out after the plasma etch step forming the source side opening 260 and the drain side opening 262. The etch clean step may result in a retrograde profile 243 of the first dielectric layer 240 underneath the source side contact etch stop 246 and the drain side contact etch stop 247. For example, the ends of the first dielectric layer 240 are recessed in comparison to the respective ends of the source side contact etch stop 246 and the drain side contact etch stop 247 at the borders of the source side opening 260 and the drain side opening 262 facing the gate electrode p-type GaN stack 224. Moreover, steps (or ledges) 245 may form as a result of the etch clean step at the borders of the source contact opening 260 and drain contact opening 262 facing opposite the gate electrode p-type GaN stack 224. The source side contact etch stop 246 and drain side contact etch stop 247 extend over the vertical edges (or sidewalls) of the gate electrode p-type GaN stack 224. Portions of the respective source side contact etch stop 246 and the drain side contact etch stop 247 extending over the sidewalls of the gate electrode p-type GaN stack 224 prevents potential leakage or reliability mechanisms as described above with respect to the contact etch stop 146 of the GaN FET 102.

A source metal contact 264 and a drain metal contact 266 are formed by depositing and patterning a metal layer (e.g., the metal layer 164 described with reference to FIG. 1F) over the second dielectric layer 254, the source opening 260, the drain opening 262, the source side etch stop 246, and the drain side etch stop 247. As shown in FIG. 2, while the source opening 260 and the drain opening 262 are formed (e.g., using the plasma etch process 158 described with reference to FIG. 1E), the source and drain openings 260 and 262 may extend through the barrier layer 212 and stops within the channel layer 208. A gate contact (not specifically shown) may be formed outside of the plane of the cross section of FIG. 2. The source side contact etch stop 246 extends from the top source side corner of the gate electrode p-type GaN stack 224 over the sidewall of the gate electrode p-type GaN stack 224 to the source region 232. Similarly, the drain side contact etch stop 247 extends from the top drain side corner of the gate electrode p-type GaN stack 224 over the sidewall of the gate electrode p-type GaN stack 224 to the drain region 234. The source side etch stop 246 and the drain side contact etch stop 247 provide means to eliminate metal residue over or near the sidewalls of the gate electrode p-type GaN stack 224.

FIG. 3A through FIG. 3E are cross sections of an example microelectronic device 300 with a GaN FET 302 containing a contact etch stop depicted in successive stages of an example method of formation. The GaN FET 302 may be an example of or include aspects of the GaN FET 102. FIG. 3A shows a cross section of the microelectronic device 300 including the GaN FET 102 at a point in an example method of forming the GaN FET 302 after the p-type GaN layer 120 has been formed and patterned—e.g., using photolithography and etch process steps similar to those described with reference to FIG. 1A. Subsequently, a dielectric layer 310 (e.g., a dielectric layer similar to the first dielectric layer 140) has been deposited and patterned to form an opening 312 to expose a portion of the p-type GaN layer 120.

FIG. 3B shows the gate metal layer 122 is formed to fill the opening 312. FIG. 3C shows that the gate metal layer 122 is patterned (e.g., using photolithography and etch process steps similar to those described with reference to FIG. 1A) to form a gate electrode p-type GaN stack 324. FIG. 3D shows that the first dielectric layer 140 is formed over the gate electrode p-type GaN stack 324 and over the barrier layer 112 adjacent to the gate electrode p-type GaN stack 324. Subsequently, the process steps described with reference to FIGS. 1C through 1F can be carried out to generate the GaN FET 302 as shown in FIG. 3E. The GaN FET 302 is different than the GaN FET 102 in that the p-type GaN layer 120 and the gate metal layer 122 have been separately patterned to form the gate electrode GaN stack 324 prior to forming the first dielectric layer 140.

Although foregoing example GaN FETs 102, 202, and 302 are shown to include a p-GaN layer as part of their gate structures (e.g., the gate electrode p-type GaN stack 124, 224, and 324), the present disclosure is not limited thereto. For example, one or more of the described self-aligned contacts can be formed as either a source contact and/or a drain contact of GaN FETs (or other FETs, such as silicon-based FETs, SiC-based FETs, or the like) exclusive of the p-GaN layer in their gate structures. Moreover, such self-aligned contacts can be connected to one or more field plates disposed over the gate structure as described herein independent of the presence of the p-GaN layer in the gate structure.

What is claimed is:

1. A field effect transistor (FET), comprising:
a heterojunction layer over a substrate;
a gate structure on the heterojunction layer;
a first dielectric layer over the gate structure, the first dielectric layer extending towards a source contact opening located at a first side of the gate structure and towards a drain contact opening located at a second side of the gate structure opposite the first side;
a contact etch stop on the first dielectric layer, the contact etch stop extending from the source contact opening to at least partially over the gate structure, the contact etch stop being an electrically conducting material; and
a metal layer contacting a source region of the heterojunction layer corresponding to the source contact opening, wherein the metal layer and the contact etch stop are connected in a region between the gate structure and the source contact opening.

2. The FET of claim 1, wherein the heterojunction layer includes a channel layer of a first III-N material over the substrate and a barrier layer of a second III-N material on the channel layer.

3. The FET of claim 1, wherein the gate structure includes a p-type GaN gate layer on the heterojunction layer and a gate metal layer on the p-type GaN gate layer.

4. The FET of claim 1, wherein the metal layer forms a stretch contact extending from the source region to at least partially over a contact etch stop.

5. The FET of claim 1, wherein an end of the contact etch stop is aligned with an end of the first dielectric layer at the source contact opening.

6. The FET of claim 1, wherein an end of the first dielectric layer is recessed with respect to an end of the contact etch stop at the source contact opening.

7. The FET of claim 1, wherein the contact etch stop extends over the gate structure and extends towards the drain contact opening forming a first field plate.

8. The FET of claim 1, further comprising:
a second dielectric layer disposed between the contact etch stop and the metal layer over a portion of the gate structure, wherein the second dielectric layer extends from the portion of the gate structure to the drain contact opening, and wherein the metal layer extends over the second dielectric layer towards the drain contact opening to form a second field plate.

9. The FET of claim 8, wherein the second dielectric layer includes silicon nitride.

10. The FET of claim 1, wherein the contact etch stop includes TiW.

11. The FET of claim 1, wherein the metal layer includes aluminum.

12. The FET of claim 1, wherein the first dielectric layer includes silicon nitride.

13. A method, comprising:
forming a heterojunction layer over a substrate;
forming a gate structure on the heterojunction layer;
forming a first dielectric layer on the gate structure and on the heterojunction layer;
forming a contact etch stop on the first dielectric layer;
patterning the contact etch stop such that a portion of the contact etch stop forms a contact etch stop extension that extends from a source region of the heterojunction layer located at a first side of the gate structure to the gate structure;
forming a second dielectric layer on the contact etch stop and on the first dielectric layer exposed as a result of patterning the contact etch stop;
forming a source contact opening by removing the first dielectric layer and the second dielectric layer corresponding to the source region, wherein an end of the contact etch stop extends to the source region defining a border of the source contact opening; and
forming a metal layer contacting the source region corresponding to the source contact opening wherein the metal layer is connected to the contact etch stop at the border of the source contact opening.

14. The method of claim 13, wherein the heterojunction layer includes a channel layer of a first III-N material over the substrate and a barrier layer of a second III-N material on the channel layer.

15. The method of claim 13, wherein the gate structure includes a p-type GaN gate layer on the heterojunction layer and a gate metal layer on the p-type GaN gate layer.

16. The method of claim 13, wherein the end of the contact etch stop is aligned with an end of the first dielectric layer at the source contact opening.

17. The method of claim 13, wherein:
forming the source contact opening further includes removing the second dielectric layer corresponding to a region between the gate structure and the source contact opening and over a sidewall of the gate structure; and
the metal layer contacting the source region is connected to the contact etch stop throughout the region and over the sidewall of the gate structure.

18. The method of claim 13, wherein the metal layer forms a stretch contact that extends from the source region and contacts the contact etch stop.

19. The method of claim 18, wherein the stretch contact extends over a remaining portion of the second dielectric layer towards a drain region of the heterojunction layer located at a second side of the gate structure opposite the first side, the stretch contact forming a second field plate.

20. A field effect transistor (FET), comprising:
a channel layer of a first III-N material;
a barrier layer of a second III-N material over the channel layer;
a gate structure including a p-type GaN gate layer on the barrier layer and a gate metal layer on the p-type GaN gate layer;
a first dielectric layer over the gate structure, the first dielectric layer extending toward a source contact opening and a drain contact opening; and
a hard mask layer over the first dielectric layer, the hard mask layer including a source side contact etch stop extending from the source contact opening to at least a source side edge of the gate structure and a drain side contact etch stop extending from the drain contact opening to at least a drain side edge of the gate structure.
